(19) United States
(12) Patent Application Publication
(10) Pub. No.: US 2016/0362812 A1
(43) Pub. Date: Dec. 15, 2016

(54) OFF-AXIS SPUTTERING DEPOSITION FOR GROWTH OF SINGLE CRYSTALLINE FILMS OF A BROAD RANGE OF COMPLEX MATERIALS

(71) Applicant: Ohio State Innovation Foundation, Columbus, OH (US)

(72) Inventor: Fengyuan Yang, Dublin, OH (US)

(21) Appl. No.: 15/180,467

(22) Filed: Jun. 13, 2016

Related U.S. Application Data
(60) Provisional application No. 62/174,965, filed on Jun. 12, 2015.

(51) Int. Cl. C30B 23/08; C30B 29/22; H01J 37/34; C30B 29/02; C23C 14/34; C30B 23/06; C30B 29/52

(52) U.S. Cl. CPC C30B 23/08; C30B 23/066; C30B 29/22; C30B 29/52; C30B 29/02; C23C 14/3414; C23C 14/34; H01J 37/3426; H01J 2237/332; H01J 2237/3322

(57) ABSTRACT

Systems and methods are disclosed for growing crystalline films of a broad range of complex materials with high crystalline quality by off-axis sputtering deposition. The synthesis of sputtering targets relating to the systems and methods is also described. Materials that can be grown include binary, ternary and quaternary oxides, metals and alloys, and intermetallics with simple or complex crystal structures. The disclosed systems and methods can be regarded as a broadly applicable for the growth of many other materials having magnetic, electronic, and optical applications.

### CROSS REFERENCE TO RELATED APPLICATION

This application claims priority to and benefit of U.S. Provisional Patent Application Ser. No. 62/174,965 filed Jun. 12, 2015, which is fully incorporated by reference and made a part hereof.

### GOVERNMENT SUPPORT CLAUSE

This invention was made with government support under Grant No. DMR0820414 awarded by the National Science Foundation. The government has certain rights in this invention.

### TECHNICAL FIELD

The present disclosure is in the field of thin-film deposition.

### BACKGROUND

Sputter deposition is a technique used in manufacturing films and coatings in many industry sectors. Conventional sputtering uses the “on-axis” geometry, i.e., the substrate directly faces the sputter target. Due to the energetic bombardment of sputtered atoms, “on-axis” sputtering has been regarded as a “messy” process which may not be used to grow high quality single crystalline films and may not compete with techniques such as molecular-beam epitaxy (MBE), pulsed laser deposition (PLD), and chemical vapor deposition (CVD) for that purpose.

An off-axis geometry version of sputter deposition has been used before at high pressure, e.g., 200 mTorr. However, high pressure sputtering typically results in poor film characteristics. For example, the stoichiometry of the deposited films can be significantly off from that of the target and are relatively poor quality films.

Therefore, what are needed are devices, systems and methods that overcome challenges in the present art, some of which are described above.

### SUMMARY

Various aspects of this disclosure relate to systems and methods for growing single crystalline films of a broad range of complex materials with high crystalline quality by off-axis sputtering deposition. These materials can include binary, ternary, quaternary and more complex oxides, and intermetallics with simple or complex crystal structures. The disclosed systems and methods can be regarded as a broadly applicable for the single crystal film growth of many other materials with simple or complex structures having magnetic, electronic, dielectric, ferroelectric/piezoelectric, and optical applications. In some implementations, the synthesis of sputtering targets for growth of high quality single-crystalline films is described.

In an aspect of this disclosure, a method for thin-film deposition of a material is disclosed. The method can include: depositing, via sputtering deposition, at least one film of the material, where the sputtering deposition uses at least one sputtering target, and where the sputtering target can comprise at least one nonvolatile material. The sputtering deposition can include a sputtering target that is off-axis from (i.e., not directly facing) a substrate for material growth. Moreover, growth parameters associated with the sputtering deposition can be optimized for the sputtering deposition of the material with a high quality growth of the material. The sputtering target can include at least one pressed powder of at least one constituent material.

In some implementations, the deposited material can comprise one or more metals. The material can include intermetallic compounds. The intermetallic compounds can comprise binary intermetallic compounds. The intermetallic compounds can include at least one of ternary, quaternary, and more complex intermetallic compounds. The at least one of ternary, quaternary, and more complex intermetallic compounds can include Heusler compounds such as Co₂FeSi, Co₂FeAl, Co₂FeAl_{0.5}Si_{0.5}. The deposited material can also include one or more oxides. The oxides can include simple oxides. The oxides can include complex oxides. The complex oxides can include single perovskite oxides. The complex oxides can include double perovskite oxides. The complex oxides can include spinel oxides. The complex oxides can include Garnet oxides. The simple oxides can comprise the AOₓ compounds (e.g., NiO). The single perovskite oxides can comprise the ABO₃ compounds (e.g., SrTiO₃). The double perovskite oxides can include the A₂BB′O₆ compounds (e.g., Sr₂FeMoO₆ and Sr₂CrReO₆). The spinel oxides can include the AB₂O₄ compounds (e.g., MgAl₂O₄). The Garnet oxides can include the A₃B₅O₁₂ compounds (e.g., Y₃Fe₅O₁₂).

In other implementations, the growth parameters can include one or more of at least one sputtering gas, a total pressure of the at least one sputtering gas, an oxygen percentage in the at least one sputtering gas for oxide growth, a substrate location, a substrate temperature, a sputtering power source, and a deposition rate.

The at least one sputtering gas can include at least one inert gas (e.g., argon) and possibly more gases (e.g., oxygen for oxide growth or nitrogen, ammonia for nitride growth). The total pressure of the at least one sputtering gas includes a value from about 5 mTorr to about 15 mTorr, inclusive, depending on the at least one constituent material, in order to obtain the high quality growth of the material. The total pressure of the at least one sputtering gas can have a value from about 1 mTorr to about 30 mTorr, inclusive, in order to obtain the sufficient quality growth of the material.

The oxygen percentage in the at least one sputtering gas for oxide growth can include a value from about 0 percent oxygen in argon to about 5 percent oxygen in argon, inclusive, and is dependent on the reduction-oxidation chemistry of the at least one constituent material, in order to obtain the high quality growth of the material. The oxygen percentage in the at least one sputtering gas for oxide growth can include a value from about 0 percent oxygen in argon to about 30 percent oxygen in argon, inclusive, and can be dependent on the reduction-oxidation chemistry of the constituent materials, in order to obtain the sufficient quality growth of the deposited material.

The substrate location comprises an off-axis angle value from about 45 degrees to about 70 degrees, inclusive, with respect to a target normal direction, and moreover, can be located a distance of about 2 inch to about 5 inch, inclusive, from the target for at least one approximately 2 inch-diameter target, in order to obtain the high quality growth of the material. The substrate location can include an off-axis angle value from about 30 degrees to about 80 degrees, inclusive, with respect to a target normal direction, and moreover, can be located a distance of about 1.5 inch to about 8 inch, inclusive, from the target for at least one approximately 2 inch-diameter target, in order to obtain the sufficient quality growth of the material.

The substrate temperature can include a value from about 200 degrees centigrade to about 850 degrees centigrade, inclusive, and can be dependent on one or more thermal properties of the at least one constituent material, in order to obtain the high quality growth of the material. The substrate temperature can include a value from about 100 degrees centigrade to about 1000 degrees centigrade, inclusive, and can be dependent on one or more thermal properties of the constituent materials, in order to obtain the sufficient quality growth of the material.

The sputtering power source can comprise a direct current (DC) power source for conducting targets and a radio-frequency (RF) power source for insulating and conducting targets.

The deposition rate can comprise a value from about 5 nanometers per hour to about 120 nanometers per hour, inclusive, and is a function of the at least one constituent material, in order to obtain the high quality growth of the material. The deposition rate can comprise a value from about 3 nanometers per hour to about 1000 nanometers per hour, inclusive, in order to obtain the sufficient quality growth of the material.

The substrate temperature can include a value from about 300 degrees centigrade to about 500 degrees centigrade, inclusive, in order to obtain the material including metals and metal-alloys. The substrate temperature can include a value from about 200 degrees centigrade to about 500 degrees centigrade, inclusive, for obtaining the material comprising binary intermetallic compounds. The substrate temperature comprises a value from about 400 degrees centigrade to about 700 degrees centigrade, inclusive, for obtaining the material comprising complex intermetallic compounds. The substrate temperature can include a value from about 400 degrees centigrade to about 600 degrees centigrade, inclusive, for obtaining the material comprising simple binary oxides. The substrate temperature can include a value from about 500 degrees centigrade to about 850 degrees centigrade, inclusive, for obtaining the material comprising complex oxides.

The at least one pressed powder of the sputtering target can include at least one sub-micron fine powder of at least one constituent material. The at least one pressed powder can be compressed in order to form the at least one sputtering target. The at least one pressed powder can be compressed using at least one die. The at least one die can be circular, rectangular, polygonal, cylindrical, U-shape, ring-shape, or any other shape used for sputtering deposition. A supporting cup can be used to hold the at least one sputtering target together, and can be made from at least one nonmagnetic material. The at least one sputtering target can include at least one circular sputtering target having an about 2 inch diameter and a thickness up to and including about 0.25 inch. Moreover, the at least one sputtering target having an about 2 inch diameter, and the pressure for compressing the pressed powders in order to form the at least one sputtering target can range from about 1 metric ton to about 20 metric tons, inclusive, and can be dependent on the at least one constituent material.

The deposited material can be characterized by crystallography. The crystallography can comprise X-ray diffraction (XRD). The XRD comprises one or more of a 8-28 or a 2θ-ω scan. The XRD technique comprises Laue oscillation peak analysis.

In another aspect of the disclosure, a system for thin-film deposition of a material is disclosed. The system can include a sputtering deposition tool for depositing at least one film of the material. The sputtering deposition tool can use at least one sputtering target. The material can include at least one nonvolatile single crystalline film. The sputtering deposition tool can include the at least one sputtering target which is off-axis from a substrate for material growth. Growth parameters associated with the sputtering deposition tool can be optimized for a sputtering deposition of the material with at least one of a high quality growth and a sufficient quality growth of the material. The at least one sputtering target can include at least one pressed powder of at least one constituent material.

In some implementations, the deposited material can comprise one or more metals. The material can include intermetallic compounds. The intermetallic compounds can comprise binary intermetallic compounds. The intermetallic compounds can include at least one of ternary, quaternary, and more complex intermetallic compounds. The at least one of ternary, quaternary, and more complex intermetallic compounds can include Heusler compounds such as Co₂FeSi, Co₂FeAl, Co₂FeAl_{0.5}Si_{0.5}. The deposited material can also include one or more oxides. The oxides can include simple oxides. The oxides can include complex oxides. The complex oxides can include single perovskite oxides. The complex oxides can include double perovskite oxides. The complex oxides can include spinel oxides. The complex oxides can include Garnet oxides. The simple oxides can comprise the AOₓ compounds (e.g., NiO). The single perovskite oxides can comprise the ABO₃ compounds (e.g., SrTiO₃). The double perovskite oxides can include the A₂BB′O₆ compounds (e.g., Sr₂FeMoO₆ and Sr₂CrReO₆). The spinel oxides can include the AB₂O₄ compounds (e.g., MgAl₂O₄). The Garnet oxides can include the A₃B₅O₁₂ compounds (e.g., Y₃Fe₅O₁₂).

In other implementations, the growth parameters can include one or more of at least one sputtering gas, a total pressure of the at least one sputtering gas, an oxygen percentage in the at least one sputtering gas for oxide growth, a substrate location, a substrate temperature, a sputtering power source, and a deposition rate.

The at least one sputtering gas can include at least one inert gas (e.g., argon) and possibly more gases (e.g., oxygen for oxide growth or nitrogen, ammonia for nitride growth). The total pressure of the at least one sputtering gas include a value from about 5 mTorr to about 15 mTorr, inclusive, depending on the at least one constituent material, in order to obtain the high quality growth of the material. The total pressure of the at least one sputtering gas can have a value from about 1 mTorr to about 30 mTorr, inclusive, in order to obtain the sufficient quality growth of the material.

The oxygen percentage in the at least one sputtering gas for oxide growth can include a value from about 0 percent oxygen in argon to about 5 percent oxygen in argon, inclusive, and is dependent on the reduction-oxidation chemistry of the at least one constituent material, in order to obtain the high quality growth of the material. The oxygen percentage in the at least one sputtering gas for oxide growth can include a value from about 0 percent oxygen in argon to about 30 percent oxygen in argon, inclusive, and can be dependent on the reduction-oxidation chemistry of the constituent materials, in order to obtain the sufficient quality growth of the material.

The substrate location comprises an off-axis angle value from about 45 degrees to about 70 degrees, inclusive, with respect to a target normal direction, and moreover, can be located a distance of about 2 inch to about 5 inch, inclusive, from the target for at least one approximately 2 inch-diameter target, in order to obtain the high quality growth of the material. The substrate location can include an off-axis angle value from about 30 degrees to about 80 degrees, inclusive, with respect to a target normal direction, and moreover, can be located a distance of about 1.5 inch to about 8 inch, inclusive, from the target for at least one approximately 2 inch-diameter target, in order to obtain the sufficient quality growth of the material.

The substrate temperature can include a value from about 200 degrees centigrade to about 850 degrees centigrade, inclusive, and can be dependent on one or more thermal properties of the at least one constituent material, in order to obtain the high quality growth of the material. The substrate temperature can include a value from about 100 degrees centigrade to about 1000 degrees centigrade, inclusive, and can be dependent on one or more thermal properties of the constituent materials, in order to obtain the sufficient quality growth of the material.

The sputtering power source can comprise a direct current (DC) power source for conducting targets and a radio-frequency (RF) power source for insulating targets.

The deposition rate can comprise a value from about 5 nanometers per hour to about 120 nanometers per hour, inclusive, and is a function of the at least one constituent material, in order to obtain the sufficient quality growth of the material. The deposition rate can comprise a value from about 3 nanometers per hour to about 1000 nanometers per hour, inclusive, in order to obtain the sufficient quality growth of the material.

The substrate temperature can include a value from about 300 degrees centigrade to about 500 degrees centigrade, inclusive, in order to obtain the material including metals and metal-alloys. The substrate temperature can include a value from about 200 degrees centigrade to about 500 degrees centigrade, inclusive, for obtaining the material comprising binary intermetallic compounds. The substrate temperature comprises a value from about 400 degrees centigrade to about 700 degrees centigrade, inclusive, for obtaining the material comprising complex intermetallic compounds. The substrate temperature can include a value from about 400 degrees centigrade to about 600 degrees centigrade, inclusive, for obtaining the material comprising simple binary oxides. The substrate temperature can include a value from about 500 degrees centigrade to about 850 degrees centigrade, inclusive, for obtaining the material comprising complex oxides.

The at least one pressed powder of the sputtering target can include at least one sub-micron fine powder of at least one constituent material. The at least one pressed powder can be compressed in order to form the at least one sputtering target. The at least one pressed powder can be compressed using at least one die. The at least one die can be circular, rectangular, polygonal, cylindrical, U-shape, ring-shape, or any other shape used for sputtering deposition. A supporting cup can be used to hold the at least one sputtering target together, and can be made from at least one nonmagnetic material. The at least one sputtering target can include at least one circular sputtering target having an about 2 inch diameter and a thickness up to and including about 0.25 inch. Moreover, the at least one sputtering target having an about 2 inch diameter, and the pressure for compressing the pressed powders in order to form the at least one sputtering target can range from about 1 metric ton to about 20 metric tons, inclusive, and can be dependent on the at least one constituent material.

The deposited material can be characterized by crystallography. The crystallography can comprise X-ray diffraction (XRD). The XRD comprises one or more of a θ-2θ or a 2θ-ω scan. The XRD technique comprises Laue oscillation peak analysis.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF THE DRAWINGS

The components in the drawings are not necessarily to scale relative to each other and like reference numerals designate corresponding parts throughout the several views:

FIG. 1 shows a representative deposition system for the off-axis sputtering using the disclosed systems and methods.

FIG. 2 shows an example flow chart overview of the steps involved in the preparation of the sputtering targets.

FIG. 3A shows an SEM image of complex oxide Sr₂FeMoO₆ powders with sub-micron particles.

FIG. 3B shows a schematic of a pressed target of fine powders with a copper supporting cup.

FIGS. 4A-4B show a schematic of the difference in the distributions of sputtered atoms between a conventional solid, 100% dense sputtering target and a fine powder target for the same binary compound AB as an example. The solid, dense target results in variation of film composition for substrates positioned at different locations. The fine powder targets described herein give uniform composition in the deposited films across a wide range of sample locations.

FIGS. 5A-5C show the unprecedented crystal quality in double perovskite single-crystal films.

FIG. 6 shows an XRD ω-2θ scans of a 19-nm SiGe layer on Si(001) substrate capped by a Si layer of various thicknesses, taken from Hartmann, et al., Semicond. Sci. Technol. 28, 025018 (2013), as an example of XRD Laue oscillations in an established high quality semiconductor material.

FIGS. 7A-7B show high crystal quality in single-perovskite SrTiO₃ films.

FIGS. 8A-8C show excellent ordering in TEM images of Sr₂FeMoO₆ single-crystal films made with the disclosed systems and methods, which are compared to FIG. 8D reported in Appl. Phys. Lett. 88, 121912 (2006).

FIGS. 9A-9B show a high-degree of crystal ordering in TEM images of Sr₂CrReO₆ films made with the disclosed systems and methods, which are compared to FIG. 9C reported in Phys. Status Solidi A 208, 232 (2011).

FIGS. 10A-10C show the XRD scans of high crystal quality Sr₂CrReO₆ single-crystal films made with the disclosed systems and methods, which are compared to FIG. 10D reported in J. Magn Magn. Mater. 322, 1217 (2010).

FIGS. 11A-11B show electrical resistivity measurements of the Sr₂CrReO₆ films made by with the disclosed systems and methods, which are compared to FIG. 11C reported in J. Magn Magn. Mater. 322, 1217 (2010).

FIGS. 12A-12B show the XRD scans of high crystal quality YIG single-crystal films made with the disclosed systems and methods, which are compared to FIG. 12C reported in Appl. Phys. Lett. 101, 152405 (2010).

FIG. 13A show the large spin transport signals in YIG/Pt bilayers made with the disclosed systems and methods. The measured millivolt inverse spin Hall Effect voltages are orders of magnitude larger than previous reports.

FIG. 13B shows an inverse spin Hall effect voltage measurement on YIG/Pt bilayers reported in Nature 464, 262 (2010) with a signal of a few microvolt.

FIG. 14 shows an XRD scan of high crystal quality spinel oxide MgAl₂O₄ films.

FIGS. 15A-15D show the XRD scans of high crystal quality Heusler compound Co₂FeAl_{0.5}Si_{0.5} single-crystal films made with the disclosed systems and methods, which are compared to FIG. 15E reported in Phys. Rev. B 74, 174426 (2006).

FIG. 16A shows the magnetoresistance of films made with the disclosed systems and methods, which is compared to FIG. 16B reported in Phys. Rev. B 74, 174426 (2006).

FIGS. 17A-17B show high crystal quality in simple binary oxide single-crystal NiO films.

FIG. 18 shows a 2θ-ω XRD scan of a FeGe single-crystal film grown on Si substrate.

FIG. 19 shows a TEM image of a Pt single-crystal film grown on a Sr₂FeMoO₆ epitaxial film.

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems may be understood more readily by reference to the following detailed description of preferred embodiments and the Examples included therein and to the Fig.'s and their previous and following description.

In one aspect of the disclosure, off-axis sputter deposition methods and systems are described. These methods and systems may differ significantly from conventional on-axis and off-axis sputter deposition, resulting in improved crystalline quality for a broad range of deposited materials. Moreover, the disclosed methods and systems rely on unconventional preparation methods of a sputtering target for the growth of complex films with stoichiometric composition, high crystalline ordering, sharp interfaces and smooth surfaces.

For purposes of this disclosure, a sputtering target can comprise a material that is used to create thin films in sputter deposition. During this process, atoms can be ejected from conventional sputtering targets by accelerated gaseous ions and coat a substrate. In this disclosure, unconventional preparation methods of a sputtering target are implemented. The effectiveness of these unconventional sputtering targets can depend on several factors, including their composition.

In one aspect of the disclosure, off-axis sputtering deposition methods and systems are described that can be used to grow single crystalline films of nonvolatile deposited materials, for example, simple metals, alloys, intermetallic compounds, simple binary oxides, complex oxides, semiconductors, and the like. On a broad level, the deposited materials can include, but not be limited to metals (e.g., Pt), intermetallic compounds, and oxides. The metals can include, for example, elemental metals (e.g., Pt) and alloys (e.g., Ni₈₁Fe₁₉). The intermetallic compounds can include, for example, binary intermetallic compounds (e.g. FeGe), ternary and quaternary intermetallic compounds (e.g., Co₂FeSi, Co₂FeAl, Co₂FeAl_{0.5}Si_{0.5}). The oxides can include, for example, simple oxides (e.g. NiO) and complex oxides. The complex oxides can further include: single perovskite oxides (e.g. SrTiO₃), double perovskite oxides (e.g. Sr₂FeMoO₆, Sr₂CrReO₆), spinel oxides (e.g. MgAl₂O₄), and Garnet oxides (e.g. Y₃Fe₅O₁₂).

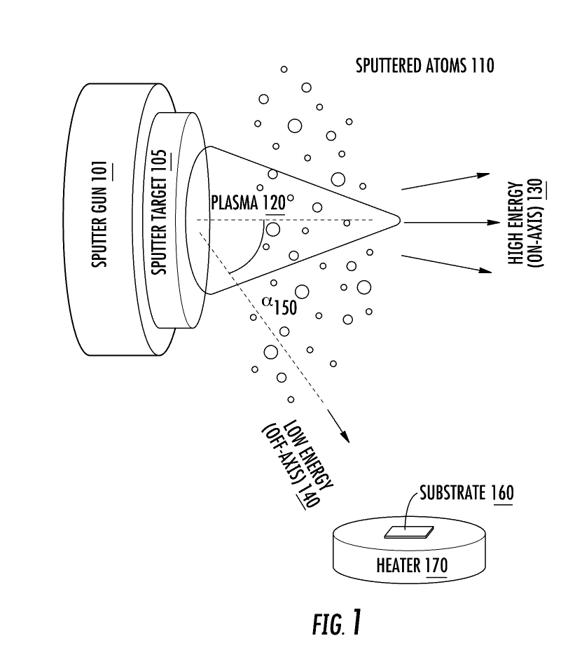

FIG. 1 shows a representative deposition system for the off-axis sputtering using the disclosed systems and methods. Generally, the system comprises a sputter gun 101, a sputter target 105, a substrate 160 and a heater 170 for heating the substrate 160. Generally, the sputter gun 101 confines charged plasma 120 with ions and electrons close to the surface of the sputter target 105. In a magnetic field, electrons follow helical paths around magnetic field lines undergoing more ionizing collisions with gaseous neutral atoms near the target 105 surface than would otherwise occur. The sputter gas typically comprises an inert gas such as argon. The extra argon ions created as a result of these collisions leads to a higher deposition rate. It also means that the plasma can be sustained at a lower pressure. The sputtered atoms are neutrally charged and so are unaffected by the magnetic trap. The ionized sputter gas (e.g., argon) are accelerated toward a sputter target 105 by an applied voltage to a sputter gun 101 and collide with a sputter target 105 with an energy greater than the surface binding energy of the atoms in the sputter target 105, leading to sputtered atoms 110. The types of sputter guns can include, but not limited to, conventional magnetron sputter guns, high power impulse magnetron sputter guns, and ion-beam sputter guns. The shape of the sputtering targets can be planar circular, planar rectangular, circular ring-shape, rectangular ring-shape, polygonal, U-shape, cylindrical, or any other shapes that are appropriate for sputtering deposition. The primary particles for the sputtering process can be supplied in a number of ways, for example, by a plasma 120 confined in front of the sputtering targets by magnets in the sputtering guns, by a plasma generated in a side chamber adjacent to the sputtering targets and guided/accelerated toward the sputtering targets, or by an ion source as in ion-beam sputtering. The sputtering power sources can be direct-current (DC) sputtering for conducting sputtering targets and radio-frequency (RF) sputtering for both insulating and conducting sputtering targets. The type of sputtering can include non-reactive sputtering, where the sputtering targets and the deposited films have approximately the same composition, and reactive sputtering, where the sputtering targets are metals or intermetallics and oxygen or nitrogen gaseous source is supplied for the deposition of oxide or nitride films. A high-energy direction (on-axis) 130 and a low-energy direction (off-axis) 140 can be defined with respect to a surface normal direction from the sputter target 105. An angle α 150 can be defined between the surface normal direction from the sputter target 105 and vector pointing from the center of the sputter target 105 to the center of the substrate 160. Deposition of the deposited material occurs on the substrate 160. Conventional sputtering uses almost exclusively the on-axis geometries 130 (α is close to 0°), where the substrate 160 and/or heater 170 can be located directly facing the sputtering target 105, and as a result, the substrate is bombarded by high-energy atoms ejected from the sputtering target 105 and the particles in the plasma 120. In the off-axis geometries 140 (α is away from 0°), the substrate 160 and/or heater 170 can be located in the direction of low-energy atoms, enabling deposition of high quality films. The heater 170 can be used before, during, or after deposition to heat the substrate 160 in order to provide the optimal deposition temperatures for the deposited materials to form high crystalline ordering with the desired composition. The heater may comprise, for example, Inconel heaters, boron nitride heaters, graphite heaters, tungsten heaters, refractory metal heaters, and halogen lamp heaters. The heaters can have graphite, silicon carbide, or boron nitride coatings.

The off-axis geometry have been used in sputtering at high pressure, e.g., approximately 200 mTorr. At such a high pressure, most atoms sputtered off the target may go through many scatterings with the sputtering gas (for example, argon and possibly, oxygen) and may slow down before depositing on the substrate positioned at the side of the target. Consequently, energetic bombardment can be minimized. However, the high pressure sputtering can result in the stoichiometry of the deposited films being different from that of the target due to different scattering profiles of different species of atoms. This can lead to a relatively poor quality of the films.

The disclosed off-axis sputtering deposition methods and systems differs from the conventional on-axis and off-axis sputtering techniques, resulting in significantly improved crystalline quality for a broad range of deposited materials. The energetic bombardment problem in conventional sputtering techniques can be eliminated at much lower pressure, such as approximately 5 to approximately 15 mTorr, by positioning the substrate within a calibrated range of angle α with respect to the target normal direction. In particular, the angle α between the substrate and the target normal direction can take a value from 30° and 80° for high quality film growth. Smaller angle α results in higher deposition rate but increasing bombardment damage the films. Larger α results in lower bombardment damage and lower deposition rate. At low sputtering pressure (low as compared to the high pressure, e.g., approximately 200 mTorr used previously), the atoms may only go through a few scattering events before landing on the substrate 160, improving the stoichiometry of the deposited films. The optimal range of angle α 150 can be from approximately 45° and approximately 70°, while films with slightly reduced quality can still be grown at angle α 150 between 30° and 45° as well as from approximately 70° and approximately 80°. At approximately α<30°, bombardment damage increases and the geometry can be close to an on-axis sputtering. At approximately α>80°, the deposition rate may become very low. An α from approximately 50° to approximately 60° may work for most non-volatile deposited materials.

Another feature of the disclosed systems and methods includes a set of growth parameters optimized for the deposition of high quality single-crystal films of a wide range of deposited materials. All deposited materials grown using the disclosed methods and systems share similar parameters, e.g. total pressure of sputtering gas, sample position, and target requirements, which makes the disclosed methods and systems broadly applicable for many deposited materials without extensive development efforts. Other variables can include the oxygen partial pressure and substrate temperature, both of which can be predicted by the chemistry and thermodynamics of the deposited materials.

Growth parameters enable production of high-quality films during sputtering deposition using the described systems and methods. For example, for sputtering deposition of metallic or intermetallic materials (non-oxides), argon can be used as sputtering gas; for sputtering depositions of oxides, including simple oxides and complex oxides, an appropriate amount of oxygen may need to be added to argon as sputtering gas. For oxides, the amount of oxygen can be selected by following the reduction-oxidation chemistry of the materials. The reduction-oxidation environment during the solid-state synthesis can provide valuable guidance. For oxides that are stable in air at high temperatures, approximately 0.5% to approximately 5% oxygen in argon can be a good starting point. If a reduction or inert environment is required during solid-state synthesis, a reduced amount of oxygen or no oxygen is needed. Generally, the oxygen partial pressure can range from 0% to 1% in argon. During the sputtering deposition, for optimal deposition of the described materials the total pressure of the sputtering gas can be approximately 5 mTorr to approximately 15 mTorr with approximately 10 mTorr being a good starting point.

The optimal substrate location can be as given in Table I, below, which can be applicable for all material classes. Generally, an off-axis angle α 150 of approximately 50° to approximately 60° can work well. The substrate temperature can depend on the thermodynamic properties, in particular, the melting points or decomposition temperatures of the deposition materials. For example, for metals and their alloys, the most likely substrate temperatures can be approximately 300° C. to approximately 500° C.; for simple binary intermetallic compounds, the most likely substrate temperatures can be approximately 200° C. to approximately 500° C.; for complex intermetallic compounds, the most likely substrate temperatures can be approximately 400° C. to approximately 700° C.; for simple binary oxides, the most likely substrate temperatures can be approximately 400° C. to approximately 600° C.; and for complex oxides, the most likely substrate temperatures can be approximately 500° C. to approximately 850° C. Generally, the substrate temperature ranges from 200° C. and 850° C.

The sputtering energy source can be, for example, a DC source for conducting targets and RF source for insulating and conducting targets, though other forms of deposition and energy source are contemplated within the scope of embodiments of the disclosure. The sputtering deposition rate can be between approximately 10 and approximately 100 nm per hour to start.

Aspects of the disclosure may rely on an unconventional preparation process of the sputtering target as described, which may be relevant for the growth of complex films with the desired stoichiometric composition, a high crystalline ordering, sharp interfaces and smooth surfaces.

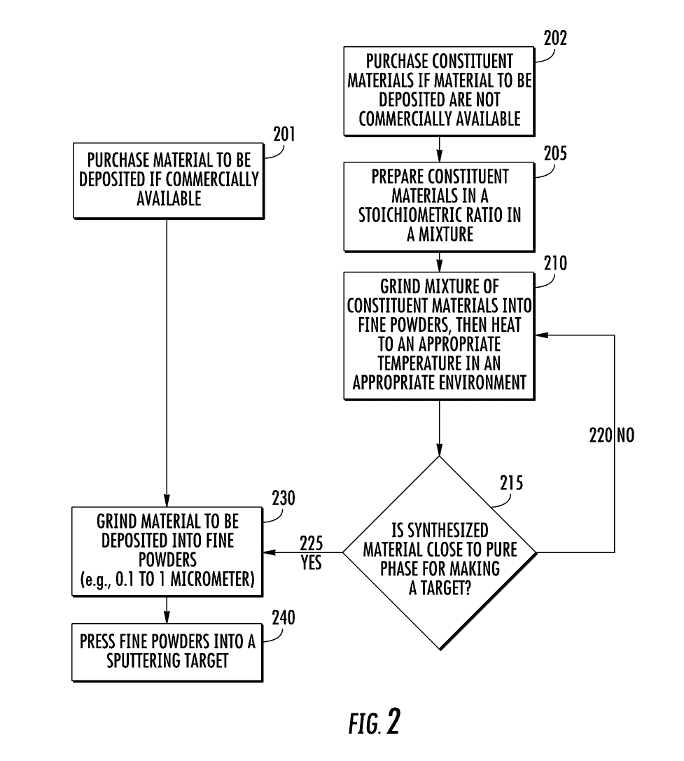

FIG. 2 shows an example flow chart overview of the steps involved in the preparation of the sputtering targets. Some examples of materials that can be used for growth of single crystalline films include: yttrium iron garnet, Y₃Fe₅O₁₂ (YIG), iron germanium intermetallic compound, FeGe, cobalt iron silicon intermetallic Heusler compound, Co₂FeSi, and strontium iron molybdate, Sr₂FeMoO₆. First, if the material to be deposited is commercially available, e.g., yttrium iron garnet, Y₃Fe₅O₁₂ (YIG), and strontium titanate, SrTiO₃, the material can be purchased 201. If the material to be deposited is not commercially available and need to be synthesized, constituent materials for the synthesis of the material to be deposited can purchased 202. The constituent materials can then be prepared into a stoichiometric ratio in a mixture 205. FeGe can be formed, for example, by mixing Fe and Ge powders in a stoichiometric ratio into a mixture. For Co₂FeSi, Co, Fe, and Si powders can be mixed in stoichiometric ratio into a mixture. For Sr₂FeMoO₆. SrCO₃, Fe₂O₃, MoO₃ powders can be mixed in stoichiometric ratio into a mixture.

The mixture of constituent materials are ground 210 into fine powders with relatively uniform sizes of, for example, about 1 micrometer (μm) or smaller. If the starting constituent materials are large pieces, e.g., approximately millimeter dimensions, they can be crushed into smaller pieces (approximately sub-millimeter size) first. Then, a grinding instrument, for example, a planetary ball mill, can be used to grind the powders into approximately sub-micrometer powders.

The ground mixture of constituent materials are heated 210 to an appropriate temperature in an appropriate environment. For example, the FeGe mixture can be heated to approximately 400° C. to approximately 600° C. in a tube furnace in hydrogen environment to form the FeGe compound. The Co₂FeSi mixture can be melted in an arc melting furnace in argon environment to form the Heusler compound. The Sr₂FeMoO₆ mixture can then be heated to approximately 1000° C. to approximately 1300° C. in a tube furnace in an environment of argon with approximately 1% to approximately 5% hydrogen. The synthesized material can be examined 215 for phases and purity using, for example, x-ray diffraction (XRD). If the material is not close to the pure phase needed for film deposition 220, further grinding and heating can be performed until close to pure phase can be synthesized.

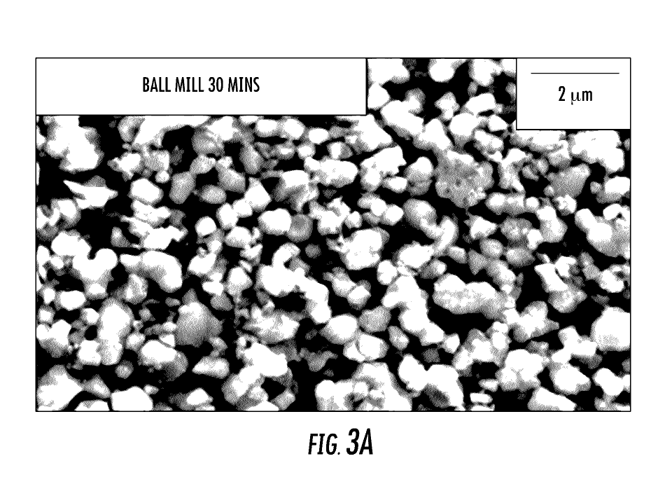

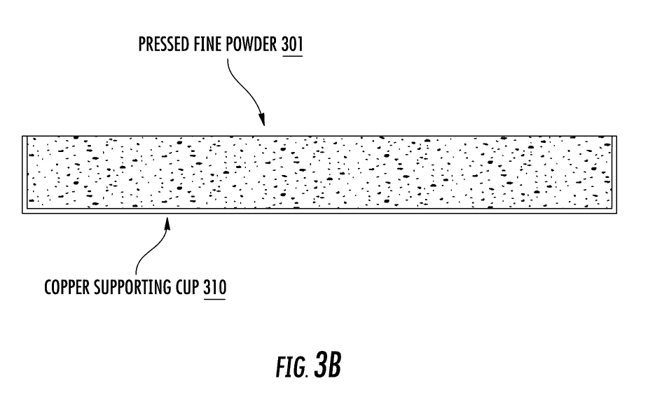

FIG. 3A shows a scanning electron microscopy (SEM) image of Sr₂FeMoO₆ powders after the grinding by a planetary ball mill for approximately 30 minutes. The particle sizes are below approximately 1 μm. A longer grinding time will make the particles down to approximately 0.1 μm.

If the synthesized material meet the requirement for phase purity 225, the materials can be ground 230 into fine powders of 0.1 to 1 micrometer in size using, for example, a planetary ball mill. If the material to be deposited can be purchased from a commercial vendor, the material can be ground the same way. Finally, the fine powders of the material to be deposited can be pressed into a sputtering target, 240. In order to press the powders into a sputtering target, a die (e.g., circular, rectangular or any other shape) may be needed. As illustrated in FIG. 3B, since the approximately sub-micrometer fine powders 301 may not be strongly bonded together, a supporting cup 310 made of nonmagnetic metals, such as, for example, copper can be used to hold the target together. For instance, a circular sputtering target of approximately 2 inches in diameter and thickness up to approximately 0.25 inches can be used. For the approximately 2 inch targets, the pressure for pressing the targets can range from approximately 1 to approximately 20 metric tons (approximately 2 MPa to approximately 40 MPa) depending on the constituent materials. The targets made this way can be structurally stable and allow for growing high quality single-crystalline films that conventional sputtering targets may be unable to achieve.

FIGS. 4A and 4B illustrate an example of binary compound materials AB to show the advantage of a sputtering target made of fine powders as compared to conventional solid dense target for deposition of stoichiometric, single crystalline films. As shown in FIG. 4A, in conventional sputtering deposition, high density (for example, approximately 100% dense) solid targets 401 may be desired. During the sputtering process, the solid, smooth target surface of the solid target 401 can be bombarded by incoming Ar+ ions 405, and both atoms A and B can be ejected from the target surface. Because they can be two different kinds of species, A and B can have different distribution profiles after they leave the target as shown in FIG. 4A. Thus, depending on the location of the substrate relative to the target, the composition of the deposited film can vary, and consequently, can be different from the target 401. This can be a major challenge of off-axis sputtering utilizing a solid, dense target 401.

The disclosed off-axis sputtering methods and systems can provide a solution to this challenge by using a sputtering target made of fine powders 420, as illustrated in FIG. 4B. As shown in FIG. 4B, the powders that comprise the target 420 are generally spherical and have approximately the same diameter. A given powder at the target surface can be represented as a micro-sphere whose surface orientation covers a solid angle of approximately 2π, i.e., half of the whole space. As the incoming ions 405 (e.g., Ar+ ions) hit this micro-sphere, the ejected atoms A and B have an approximately uniform distribution over the whole angle due to the integration of surface orientation over a solid angle of approximately 2π. Because the target surface 420 can be an ensemble of approximately sub-micrometer sized spheres instead of being flat, the sputtered atoms A and B can be uniformly distributed over space. Consequently, stoichiometric films over a broad range of off-axis angle α can be obtained.

Table I, below, describes a set of growth parameters optimized for deposition of single-crystal films of a wide range of materials. The materials described in this disclosure can be grown using the disclosed methods and systems, and share some similar parameters. The table below gives some of these growth parameters, including an optimal range for each parameter, an extended range of values that allow film growth with sufficient quality, and a range of values that may be unfavorable for growth of high quality films.

TABLE I

| | Optimal range for high | Extended range for film growth | Range may not be |
|---|---|---|---|
| Growth parameter | quality growth | with sufficient quality | favorable |
| Sputtering gases | Argon (plus oxygen for many oxides) | | |
| Total pressure of sputtering | From approx. 5 to approx. 15 | From approx. 1 to approx. 30 | Higher than 100 mTorr |
| gases | mTorr depending on the | mTorr depending on sputtering | |
| | materials | system | |
| Oxygen percentage in | approx. 0% to approx. 5% O₂ | From approx. 0% to approx. 30% | Pure oxygen (Ar may |
| sputtering gases for oxide | in Ar depending on the | O₂ in Ar depending on the | be needed for |
| growth | reduction-oxidation chemistry | reduction-oxidation chemistry of | sputtering) |
| | of the materials | the materials | |
| Substrate location | Off-axis angle approx. | Off-axis angle approx. 30° < α < | approx. α < 30° and |
| | 45° < α < 70°, distance approx. | 80°, distance approx. 1.5″ to | approx. α > 80°, distance |
| | 2″ to approx. 5″ from the | approx. 8″ from the target (for | shorter than approx. |
| | target (for approx. 2″- | approx. 2″-diameter targets) | 1.5″ or longer than |
| | diameter targets) | | approx. 8″ from the |
| | | | target (for approx. 2″ |
| | | | targets) |
| Substrate temperature | approx. 200° C. to approx. | approx. 100° C. to approx. 1000° C. | Too close to the melting |
| | 850° C. depending on the | depending on the thermal | point of the materials or |
| | thermal properties of the | properties of the materials | the substrate |
| | materials | | |
| Sputtering power source | DC power source for conducting targets and RF power source for | | |
| | insulating and conducting targets | | |
| Deposition rate | From approx. 5 to approx. 120 | From approx. 3 to approx. 1000 | Below approx. 1 |
| | nm/hour depending on the | nm/hour | nm/hour |
| | materials | | |

In another aspect of the disclosure, X-ray diffraction can be used as a characterization technique for obtaining structural information of single-crystalline and polycrystalline materials. So-called θ-2θ or 2θ-ω scans (depending on the XRD systems) can be obtained through this technique. Invoking Bragg's law, we can define:

2d sin θ=nλ,

where d is the spacing of a set of atomic planes, θ is the x-ray incidence angle with respect to the sample surface, n is a positive integer, and λ is the wavelength of the x-ray (λ=approximately 0.15405 nm for common Cu K_{α1} x-ray source). Each crystalline material gives a unique set of XRD peaks, from which structural information, for example, lattice type and lattice parameters can be retrieved.

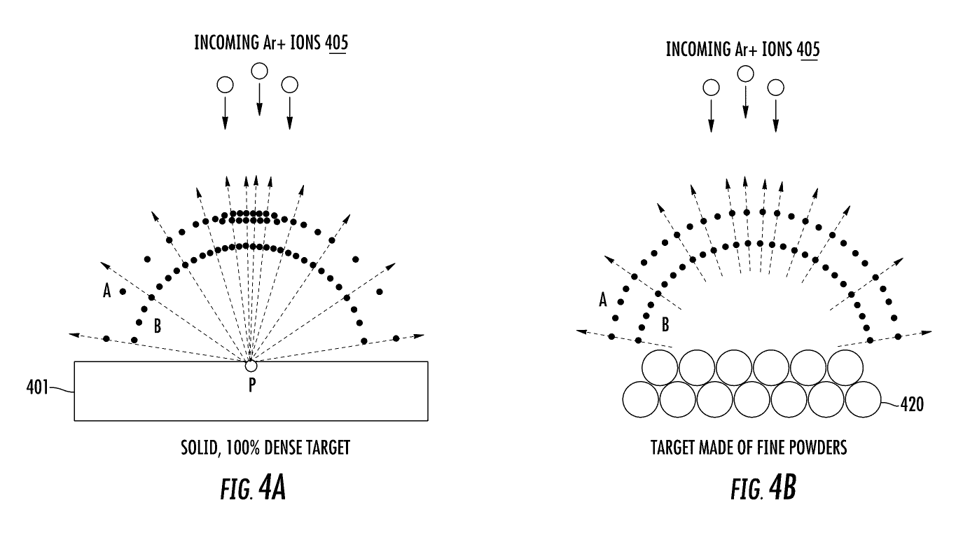

FIGS. 5A-5C show the unprecedented crystal quality in double perovskite complex oxide single-crystal films deposited using the systems and methods described herein. FIG. 5A shows the 2θ-ω and FIG. 5B shows the rocking curve XRD scans of a Sr₂CrReO₆ (SCRO) film grown on (LaAlO₃)_{0.3}(Sr₂AlTaO₆)_{0.7} (LSAT) substrate. FIG. 5C shows the 2θ-ω XRD scan of a SCRO film grown on a Sr₂CrNbO₆ (SCNO) buffer layer on SrTiO₃ (STO) substrate, where the 2θ-ω scans show pronounced Laue oscillations and the rocking curves give exceptionally narrow full-width-at-half-maximum (FWHM) values, demonstrating the high film crystal quality for the double perovskites.

For instance, FIG. 5A shows a 2θ-ω XRD scan of an approximately 90-nm thick Sr₂CrReO₆ film. The peak at 2θ=approximately 45.747° is the fourth-order (n=4) diffraction peak from the SCRO (001) planes, from which the lattice constant of SCRO can be obtained as c=approximately 0.7926 nm. The peak at the far right in FIG. 5A is from the (LaAlO₃)_{0.3}(Sr₂AlTaO₆)_{0.7} (LSAT) substrate.

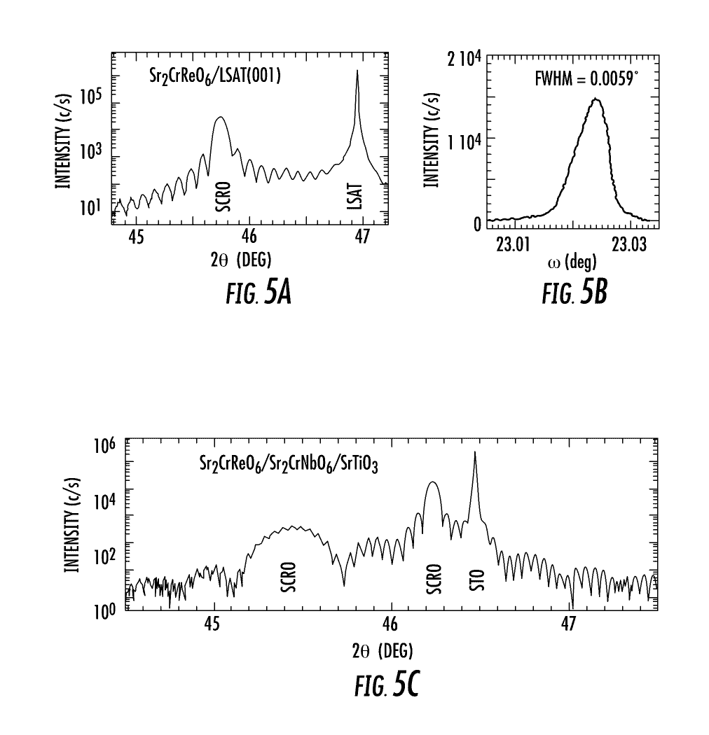

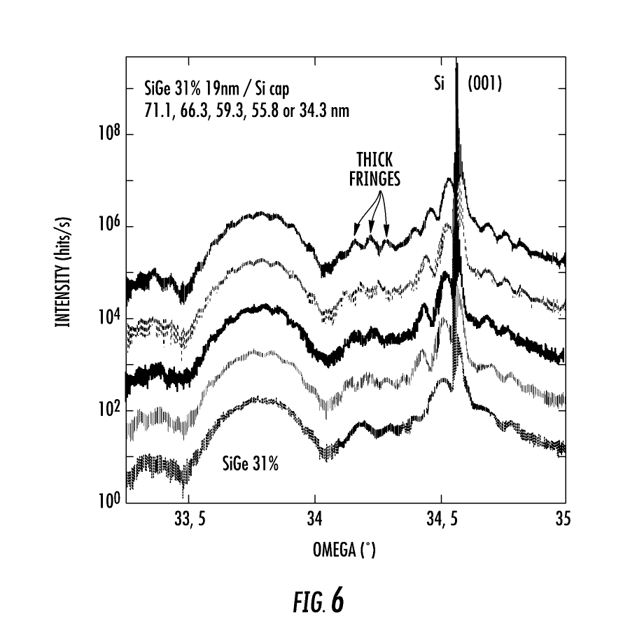

Moreover, for single crystal thin films with high crystalline ordering, highly uniform lattice constants, smooth surface and sharp interface with the substrate, the total thickness of the film can cause diffraction with the spacing d equal to the total film thickness; in the case of FIG. 5A, d=approximately 90 nm. This large spacing (approximately 90 nm) diffraction can interfere with the diffraction from the atomic spacing (e.g., 0.7926 nm), which can lead to the “beating” of two periods, and can result in multiple satellite peaks near the peak from atomic spacing (e.g., 2θ=approximately 45.747° as shown in FIG. 5A). This phenomenon is called Laue oscillations. The appearance of Laue oscillation peaks may be considered a demonstration of high quality of a single crystalline film, typically in high quality semiconductor and oxide films. For example, FIG. 6 shows an example of an approximately 19-nm SiGe single crystalline film grown on a Si(001) substrate, capped by a Si top layer of approximately 71.1, approximately 66.3, approximately 59.3, approximately 5.8, or approximately 34.3 nm. FIG. 6 shows an XRD ω-2θ scans of a 19-nm SiGe layer on Si(001) substrate capped by a Si layer of various thicknesses, taken from Hartmann, et al., Semicond. Sci. Technol. 28, 025018 (2013).

### Examples

The steps, processes and devices described below are to provide a non-limiting examples of applications of the systems and methods relating to the off-axis sputtering deposition techniques as described herein. It is to be appreciated that these are only one exemplary applications of the disclosed technology and are not to be limiting in scope or embodiments.

### ABO₃ Single Perovskite Oxides

A single-perovskite oxide film, SrTiO₃ (STO), was fabricated to demonstrate the versatility of this technique. FIGS. 7A-7B show XRD scans of a SrTiO₃ epitaxial film, which exhibit clear Laue oscillations and a narrow rocking curve with FWHM of 0.017°. FIG. 7A shows 2θ-ω and FIG. 7B shows a rocking curve XRD scan of the single perovskite SrTiO₃ single-crystal film. FIGS. 7A-7B show high crystal quality in single-perovskite films. This result confirms that disclosed methods and systems can be used to grow high quality single perovskite films. Single perovskite materials can exhibit interesting properties such as high temperature superconductivity, ferroelectricity and piezoelectricity, photovoltaics, magnetoresistance, ionic conductivity, dielectrics, and low loss in microwave frequencies, which are of great importance in electronics and telecommunication.

A₂BB′O₆ Double Perovskite Oxides

Double perovskites offer great flexibility and tunability in discovery of new materials with desired magnetic, electronic, and dielectric properties. Double perovskite epitaxial films are some of the most challenging materials to grow due to the stoichiometry and chemical complexity (4 elements), strict requirement of the oxygen environment to avoid formation of impurity phases, and difficulty in obtaining high degree of the B/B′-site ordering due to the similarity between B and B′ ions. The disclosed deposition systems and methods allow for the growth of a number of double perovskite single crystal films, including Sr₂FeMoO₆ (SFMO), Sr₂CrReO₆ (SCRO), Sr₂CrNbO₆ (SCNO), Sr₂GaTaO₆ (SGTO), Sr₂AlTaO₆ (SATO), and Sr₂Al_{0.5}Ga_{0.5}TaO₆ (SAGTO).

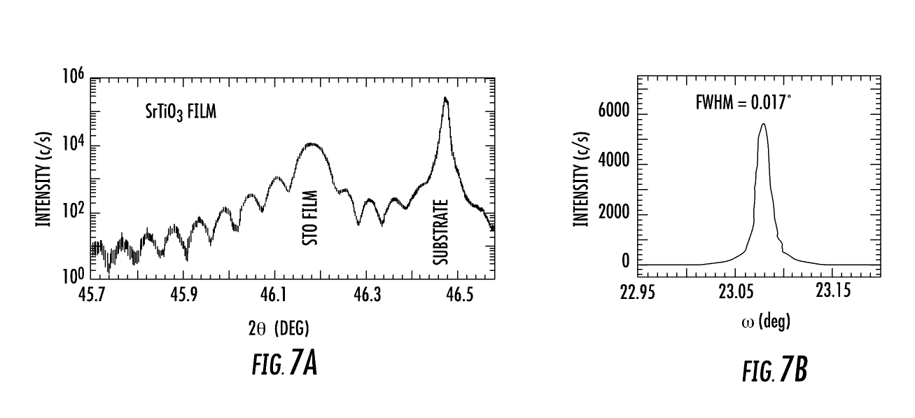

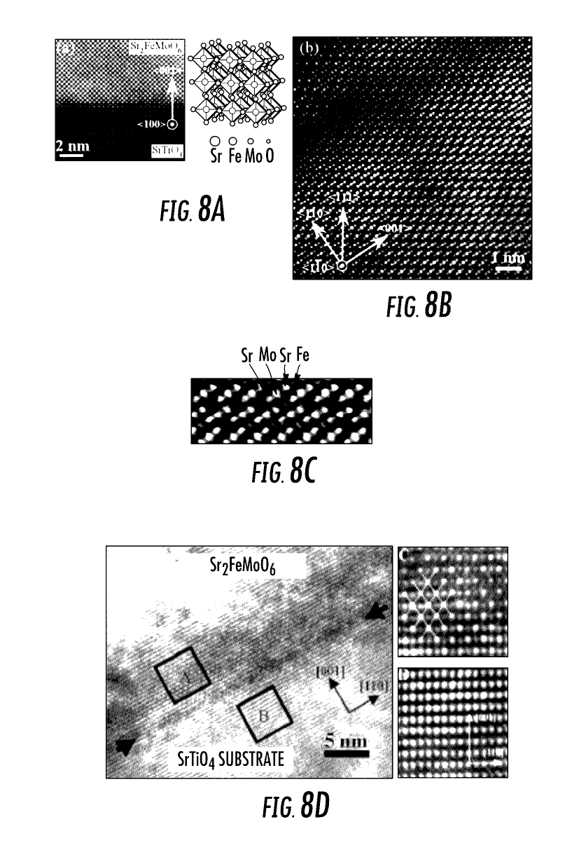

FIGS. 8A-8C show the excellent atomic ordering in Sr₂FeMoO₆ single-crystal films made with the disclosed systems and methods as compared with literature reports of Sr₂FeMoO₆ films in FIG. 8D created with alternate forms of deposition. FIG. 8A is a transmission electron microscopy (TEM) image of a Sr₂FeMoO₆ single-crystal film on SrTiO₃ substrate near the interface. FIG. 8B and FIG. 8C are TEM images of a Sr₂FeMoO₆ film with clear ordering of Sr—Mo—Sr—Fe atoms. FIG. 8D shows TEM images of a Sr₂FeMoO₆ film made by pulsed laser deposition (PLD) reported in Appl. Phys. Lett. 88, 121912 (2006), where the ordering of Sr—Mo—Sr—Fe is not as clear.

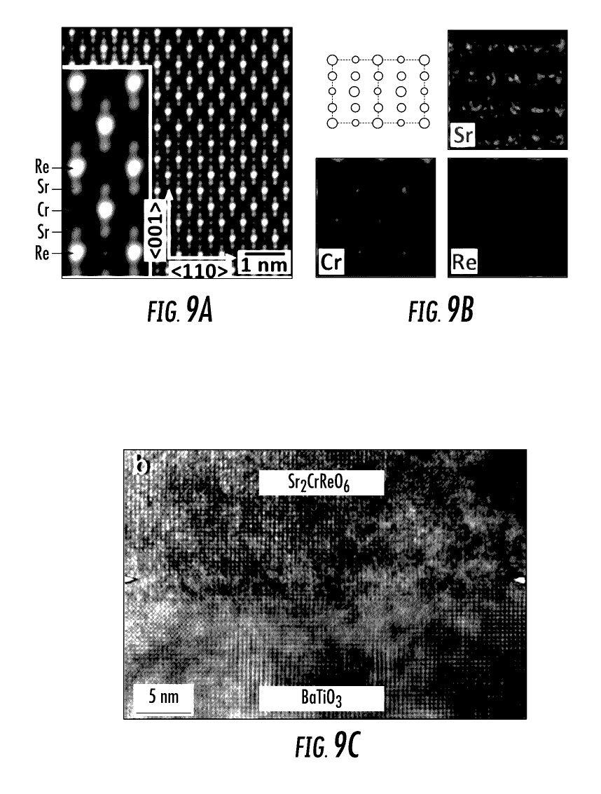

FIGS. 9A-9B show a high-degree of crystal ordering in Sr₂CrReO₆ films made with the disclosed systems and methods. FIG. 9A shows a TEM image and FIG. 9B shows energy-dispersive x-ray spectroscopy (EDS) maps of Sr₂CrReO₆, showing clear ordering of Sr, Cr, and Re. FIG. 9C shows a TEM image of a Sr₂CrReO₆ film made by pulsed laser deposition as reported in Phys. Status Solidi A 208, 232 (2011).

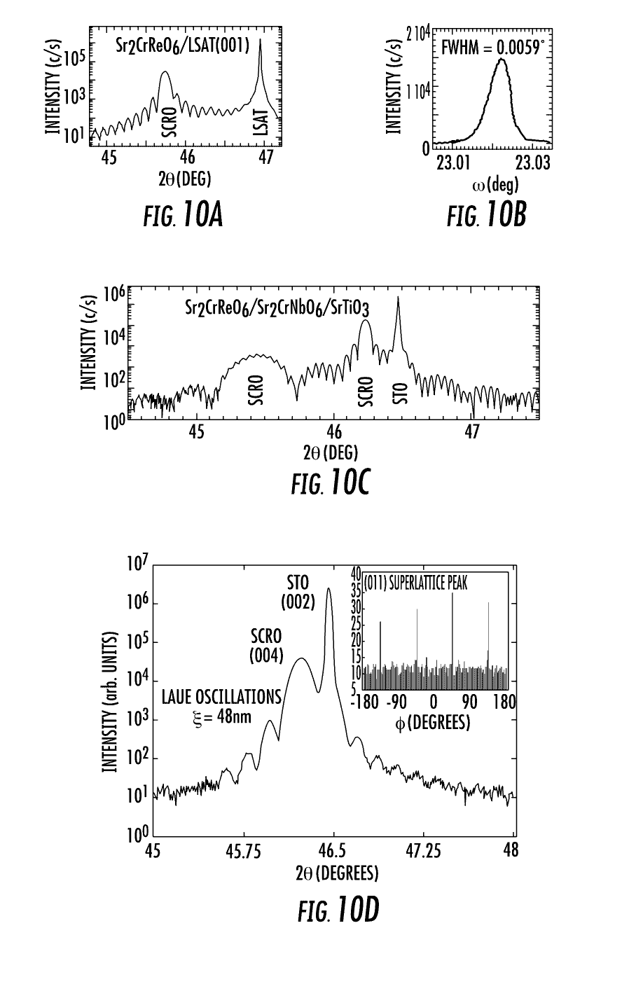

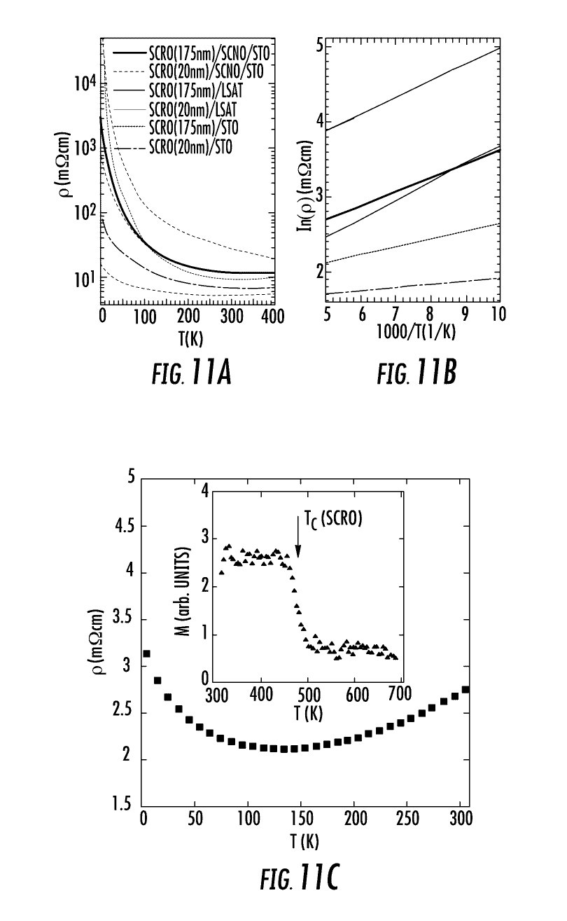

FIGS. 10A-10C show the high crystal quality in Sr₂CrReO₆ single-crystal films made with the disclosed systems and methods, as compared with the literature. FIGS. 10A-10C demonstrate high crystalline quality of Sr₂CrReO₆ films produced by the disclosed methods. The Laue oscillations reflect the high uniformity, smooth surface, sharp interface with the substrate, and excellent crystalline ordering throughout the film. FIG. 10A shows 2θ-ω and FIG. 10B shows rocking curve XRD scans of a SCRO film grown on (LaAlO₃)_{0.3}(Sr₂AlTaO₆)_{0.7} (LSAT) substrate. FIG. 10c is a 2θ-ω XRD scan of a SCRO film grown on a Sr₂CrNbO₆ (SCNO) buffer layer on SrTiO₃ (STO) substrate, where the 2θ-ω scans show pronounced Laue oscillations and the rocking curves give exceptionally narrow FWHM values, demonstrating the high film crystal quality for double perovskites. The XRD rocking curve (FIG. 10B) gives a full-width-at-half-maximum (FWHM) of approximately 0.0059°, which can be at the instrument limit of many in-house high-resolution x-ray diffractometers, demonstrating that their crystalline quality is comparable to the semiconductor epitaxial films. FIG. 10D shows a 2θ-ω XRD scan of a Sr₂CrReO₆ film made by pulsed laser deposition reported in J. Magn. Magn. Mater. 322, 1217 (2010).

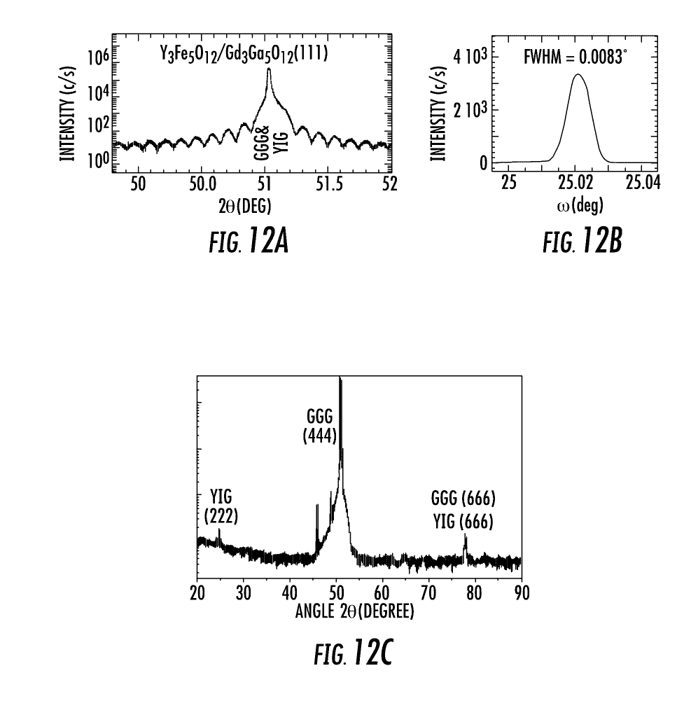

FIGS. 11A-11B show electrical resistivity measurements of the Sr₂CrReO₆ films made with the disclosed systems and methods as compared with literature reports of films created using other techniques in FIG. 11C. As a high Curie temperature ferromagnetic semiconductor, Sr₂CrReO₆ will find potential applications in electronic, optoelectronic, and magneto-electronic applications. FIG. 11A shows semi-log resistivity (ρ) vs. temperature (T) plots for six Sr₂CrReO₆ films and FIG. 11B shows Arrhenius plots ln ρ vs. 1000/T of the six films, from which the semiconducting activation energies are extracted. Because of the high quality of our Sr₂CrReO₆ films with low density of defects, semiconductor behavior was observable, i.e. exponential increase of resistivity with decreasing temperature, as expected for a semiconductor material. FIG. 11C shows the electrical resistivity of the Sr₂CrReO₆ films made by pulsed laser deposition reported in J. Magn Magn. Mater. 322, 1217 (2010). The much less change in resistivity with temperature reflects much higher defect density in the Sr₂CrReO₆ film, similar to the behavior in conventional semiconductors with high density of defects.

Double perovskite-based compounds produced by the disclosed methods can exhibit interesting properties and functionalities such as high temperature ferromagnetism, fully spin polarized ferromagnetism, and magnetoresistance which can find important applications in magnetoelectronics, data storage, and nonvolatile memory.

A₃B₅O₁₂ Garnet Oxides

Magnetic garnets, in particular, Y₃Fe₅O₁₂ (YIG), have been widely used in microwave devices, radar, telecommunication, and magnetic resonance due to their exceptionally low magnetic damping and low magnetic loss. Historically, YIG films and crystals have been grown by liquid-phase epitaxy (LPE) since the 1950s. Pulsed laser deposition (PLD) has been used to deposit epitaxial YIG films in recent years. However, due to YIG's complex crystal structure and the strict requirement for ordering, the crystalline quality of YIG was relatively poor. Using the disclosed off-axis sputtering methods and systems, the growth of YIG single-crystal thin films with improved crystalline quality can be demonstrated. These improved YIG thin film crystals led to enhanced spin transfer signals from YIG into a broad range of materials. Moreover, the materials can find application in spintronics.

FIGS. 12A-12B show high crystal quality in YIG single-crystal films made with the disclosed systems and methods as compared with literature report. FIG. 12A shows 2θ-ω and FIG. 12B shows rocking curve XRD scans of a garnet oxide Y₃Fe₅O₁₂ (YIG) single-crystal film grown on Gd₃Ga₅O₁₂ (GGG) substrate, which give clear Laue oscillations and narrow rocking curve. FIG. 12C shows 2θ-ω XRD scan of a YIG film made by pulsed laser deposition reported in Appl. Phys. Lett. 101, 152405 (2010).

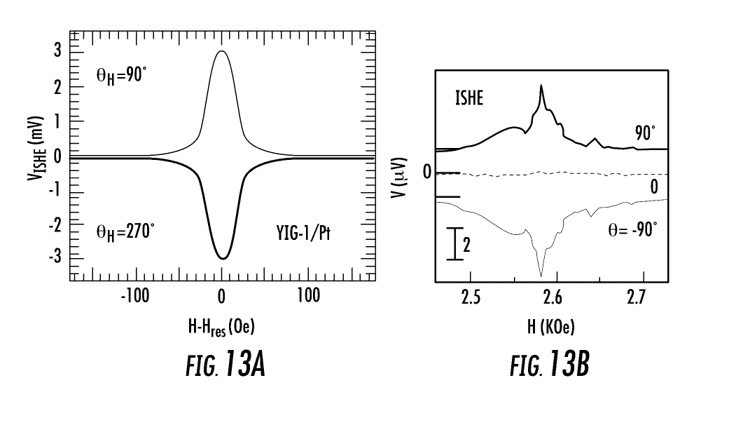

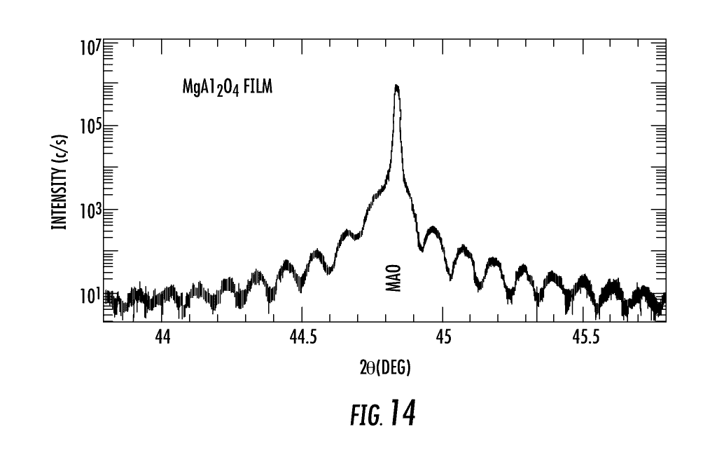

FIG. 13A shows the large spin transport signals in YIG/Pt bilayers made with the disclosed systems and methods. The measured millivolt inverse-spin-Hall-effect voltages are orders of magnitude larger than previous reports. FIG. 13B shows an inverse-spin-Hall-effect voltage measurement on YIG/Pt bilayers reported in Nature 464, 262 (2010) with a signal of a few microvolt.

AB₂O₄ Spinel Oxides

The AB₂O₄ spinel oxides are a group of oxide materials with interesting magnetic, optical and dielectric properties. The disclosed methods and system can be used to grow of one spinel oxide, MgAl₂O₄ (MAO), as shown in the 2θ-ω XRD spectrum in FIG. 14, in which the clear Laue oscillations indicate high crystalline quality. This confirms that the disclosed methods and systems can be used to growth spinel oxide single-crystal films with high crystalline quality.

### X₂YZ Heusler Intermetallic Compounds

Since the discovery of the Heusler compounds in 1901 about 800 Heusler phases have been reported. The electrical and magnetic properties of Heusler compounds range from metallic to semiconducting, and from ferromagnetic to fully spin-polarized half-metallic. The cobalt based full Heusler compounds, crystallizing in the L2₁ structure, show high Curie temperatures (up to 1100 K), high magnetic moments, and complete spin polarization at the Fermi level. These unique properties make the Co₂YZ Heusler compounds attractive candidates, for example, for integration in spintronic and spin logic devices, such as hard drives and nonvolatile memories.

Using the disclosed methods and systems single-crystal epitaxial films of a number of Heusler compounds can be grown, including Co₂FeSi, Co₂FeAl, Co₂FeAl_{0.5}Si_{0.5}, and Co₂FeAl_{0.83}Si_{0.17}.

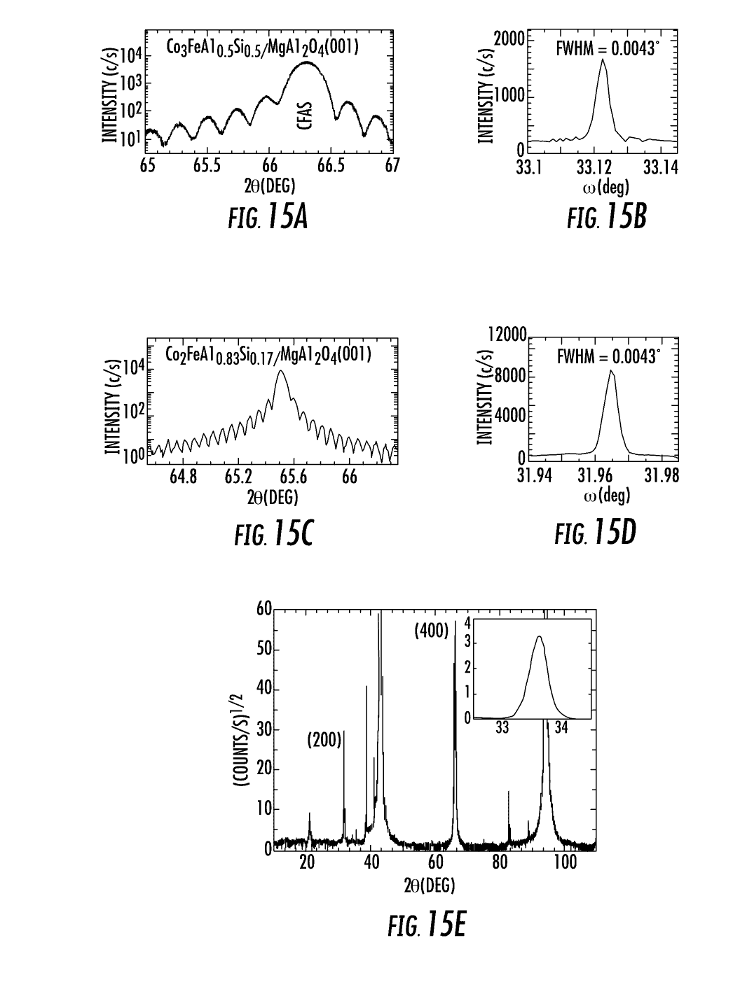

FIGS. 15A-15D show the high crystal quality in Heusler compound Co₂FeAl_{0.5}Si_{0.5} single-crystal films made with the disclosed systems and methods as compared with literature reports of similar materials created using other deposition techniques. FIG. 15A shows 2θ-ω and FIG. 15B shows rocking curve XRD scans of a Heusler intermetallic compound Co₂FeAl_{0.5}Si_{0.5} (CFAS) single-crystal film grown on MgAl₂O₄ substrate. FIG. 15C shows 2θ-ω and FIG. 15D shows rocking curve XRD scans of a Co₂FeAl_{0.83}Si_{0.17} single-crystal film grown on MgAl₂O₄. Both films show clear Laue oscillations and exceptionally narrow rocking curve. FIG. 15E shows 2θ-ω and rocking curve XRD scans of a Co₂FeSi film reported in Phys. Rev. B 74, 174426 (2006). The rocking curve of that film is 70 times broader than the films made with the disclosed systems and methods.

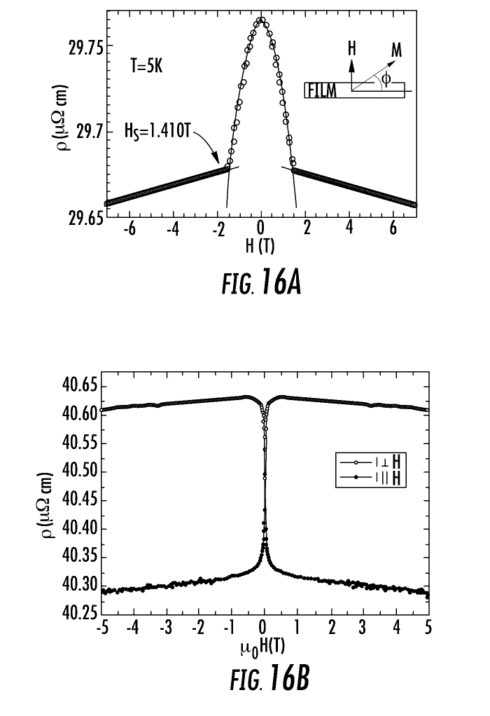

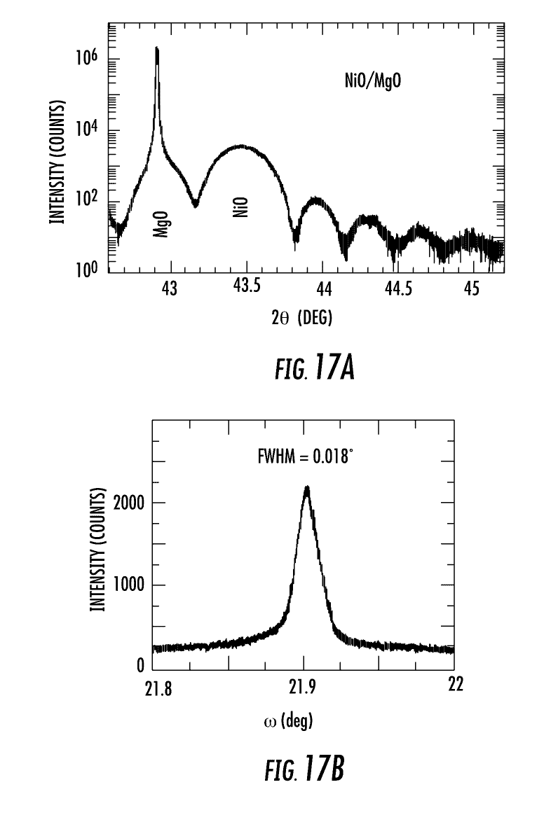

FIGS. 16A-16B show the magnetoresistance of films made with the disclosed systems and methods as compared with literature reports. FIG. 16A shows high magnetic uniformity in the Co₂FeAl_{0.5}Si_{0.5} films made with the disclosed systems and methods. Magnetoresistance of a Co₂FeAl_{0.5}Si_{0.5} film in an out-of-plane magnetic field. The blue curve is a quadratic fit for small field region and the red lines are linear fits for high field region. FIG. 16B shows magnetoresistance of a Co₂FeSi film reported in Phys. Rev. B 74, 174426 (2006). The clear distinction between the quadratic behavior at low magnetic field region and the linear field dependence at high field region in FIG. 16A is a clear indication of magnetic uniformity, which is not obvious in FIG. 16B.

The disclosed methods and systems are capable of growing high crystalline quality epitaxial films for most of the ˜800 Heusler compounds with important technological applications.

### AOₓ Binary Oxides

The disclosed systems and methods can be used to grow NiO epitaxial single-crystal films on MgO substrates. FIG. 17A shows 2θ-ω and FIG. 17B shows rocking curve XRD scans of a NiO single-crystal film grown on MgO substrate. From the XRD scans, clear Laue oscillations and a rocking curve FWHM of 0.018° are shown, demonstrating high crystalline quality. This technique can be applied to grow many other kinds of simple oxides.

### XY Intermetallic Compounds

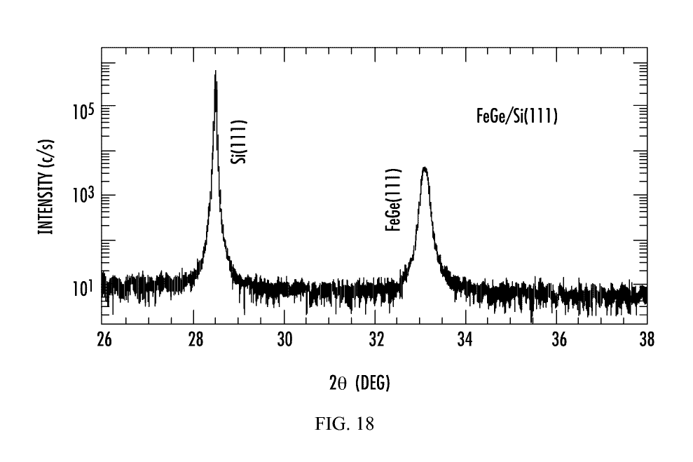

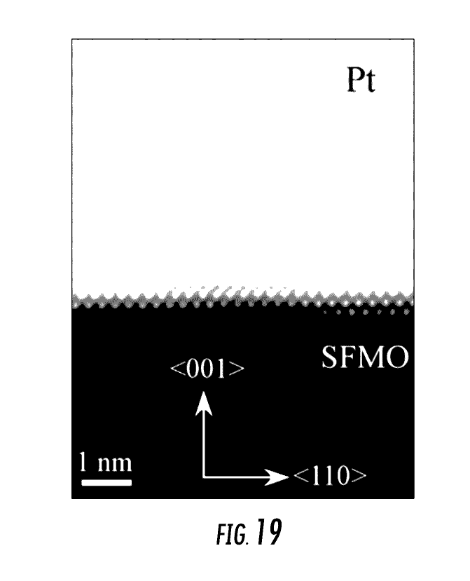

The XY intermetallic compounds can be important for both technological applications and fundamental scientific interest due to their electrical and magnetic properties. For example, the study of skyrmions in chiral magnetic materials such as FeGe has applications in magnetism. Skyrmions allows for the manipulation of nanometer-scale magnetic vortices through interactions between the spin texture and electron transport. Due to the ability to move skyrmions at low current densities, their topological stability, their small size (down to 1 nm), the ability to write and erase individual skyrmions, and multiple readout methods, there is interest in developing skyrmion materials for approaches to information storage and processing. The disclosed methods and systems can be used to demonstrate growth of phase-pure, single-crystal FeGe films on Si substrates using the invented sputtering technique. In particular, FIG. 18 shows a 2θ-ω XRD scan of a phase-pure, epitaxial FeGe single-crystal film grown on Si substrate.

### Simple Metals

Lastly, simple metals can be grown in single crystal film. For example, FIG. 19 shows a TEM image of a Pt single-crystal film grown on a Sr₂FeMoO₆ epitaxial film, where the well-ordered Pt atoms demonstrate the single-crystal nature of the Pt film.

In addition to the above classes of materials produced by the disclosed methods, the disclosed methods and system can be capable of growing single-crystal epitaxial films of many other materials.

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

Throughout this application, various publications may be referenced. The disclosures of these publications in their entireties are hereby incorporated by reference into this application in order to more fully describe the state of the art to which the methods and systems pertain.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

What is claimed is:

1. A method for thin-film deposition of a material comprising:
providing a sputtering target, wherein the sputtering target is comprised of at least one pressed powder of at least one constituent material;
providing a substrate, wherein the substrate is located at an angle relative to the sputtering target;
applying energy to the sputtering target to deposit, via sputtering deposition, at least one film of the material on the substrate, wherein the material can comprise at least one nonvolatile single crystalline film, and wherein growth parameters associated with the sputtering deposition are optimized for the sputtering deposition of the material.

2. The method of claim 1, wherein the material can comprise one or more metals, intermetallic compounds, or one or more oxides.

3. The method of claim 1, wherein the growth parameters can comprise one or more of at least one sputtering gas, a total pressure of the at least one sputtering gas, an oxygen percentage in the at least one sputtering gas for oxide growth, a substrate location, a substrate temperature, a sputtering power source, and a deposition rate.

4. The method of claim 3, wherein the substrate location comprises an off-axis angle value from about 45 degrees to about 70 degrees, inclusive, with respect to a target normal direction, and moreover, is located a distance of about 2 inch to about 5 inch, inclusive, from the target for at least one approximately 2 inch-diameter target.

5. The method of claim 3, wherein the substrate temperature comprises a value from about 200 degrees centigrade to about 850 degrees centigrade, inclusive, and is dependent on one or more thermal properties of the at least one constituent material.

6. The method of claim 3, wherein the sputtering power source comprises a direct current (DC) power source for conducting targets, a radio-frequency (RF) power source for insulating and conducting targets, or a pulsed power source, and any other power sources used for sputtering deposition.

7. The method of claim 3, wherein the deposition rate comprises a value from about 5 nanometers per hour to about 120 nanometers per hour, inclusive, and is a function of the at least one constituent material.

8. The method of claim 1, wherein the at least one pressed powder comprises at least one sub-micron fine powder of at least one constituent material.

9. A system for thin-film deposition of a material comprising:
a sputtering deposition system comprised of:
a sputter gun;
a sputter target, wherein the sputtering target is comprised of at least one pressed powder of at least one constituent material;
a substrate, wherein the substrate is located at an angle relative to the sputtering target;
a heater; and
an energy source,
wherein the material can comprise at least one nonvolatile single crystalline film deposited on the substrate using the sputter deposition system, and wherein growth parameters associated with the sputtering deposition system are optimized for a sputtering deposition of the material.

10. The system of claim 9, wherein the material can comprise one or more metals, intermetallic compounds or one or more oxides.

11. The system of claim 9, wherein the growth parameters can comprise one or more of at least one sputtering gas, a total pressure of the at least one sputtering gas, an oxygen percentage in the at least one sputtering gas for oxide growth, a substrate location, a substrate temperature, a sputtering power source, and a deposition rate.

12. The system of claim 11, wherein the substrate location comprises an off-axis angle value from about 45 degrees to about 70 degrees, inclusive, with respect to a target normal direction, and moreover, is located a distance of about 2 inch to about 5 inch, inclusive, from the target for at least one approximately 2 inch-diameter target.

13. The system of claim 11, wherein the substrate temperature comprises a value from about 200 degrees centigrade to about 850 degrees centigrade, inclusive, and is dependent on one or more thermal properties of the at least one constituent material.

14. The system of claim 11, wherein the sputtering power source comprises a direct current (DC) power source for conducting targets, a radio-frequency (RF) power source for insulating and conducting targets, or a pulsed power source.

15. The system of claim 11, wherein the deposition rate comprises a value from about 5 nanometers per hour to about 120 nanometers per hour, inclusive, and is a function of the at least one constituent material.

16. The system of claim 9, wherein the at least one pressed powder comprises at least one sub-micron fine powder of at least one constituent material.

17. A method of forming a compressed powder sputtering target comprising:
provide one or more constituent materials for deposition;
grind the one or more materials into a fine powder, wherein each particle of the fine powder has a generally uniform size; and
compress the fine powders into the sputtering target.

18. The method of claim 17, wherein the one or more constituent materials comprise metals, alloys, simplex oxides, complex oxides, binary, ternary, quaternary, and more complex intermetallic compounds.

19. The method of claim 18, wherein the one or more metals, alloys, simplex oxides, complex oxides, binary, ternary, quaternary, and more complex intermetallic compounds comprise one or more of Yttrium iron garnet, Y₃Fe₅O₁₂ (YIG); Iron germanium intermetallic compound, FeGe; Cobalt iron silicon intermetallic Heusler compound, Co₂FeSi; or Strontium iron molybdate, Sr₂FeMoO₆.

20. The method of claim 17, wherein the compressed fine powders comprise at least one sub-micron fine powder of at least one constituent material.

21. The method of claim 17, wherein at least one fine powder is compressed in order to form the at least one sputtering target.

22. The method of claim 21, wherein the fine powder is compressed using at least one die.

23. The method of claim 22, wherein the at least one die is circular, rectangular, polygonal, cylindrical, U-shape, ring-shape, or any other shape used for sputtering deposition.

24. The method of claim 17, wherein a supporting cup is used to hold the sputtering target together.

25. The method of claim 24, wherein the supporting cup is comprised from at least one nonmagnetic material.

26. The method of claim 17, wherein the sputtering target comprises at least one circular sputtering target having an about 2 inch diameter and a thickness up to and including about 0.25 inch.

27. The method of claim 26, wherein for the sputtering target having an about 2 inch diameter, the pressure for compressing the fine powders in order to form the at least one sputtering target ranges from about 1 metric ton to about 20 metric tons, inclusive, and is dependent on the one or more constituent materials.
